(19) United States
(12) Patent Application Publication
(10) Pub. No.: US 2006/0220096 A1
(43) Pub. Date: Oct. 5, 2006

(54) Tunneling-enhanced floating gate semiconductor device

(75) Inventors: Bin Wang, Seattle, WA (US); Yanjun Ma, Bellevue, WA (US)

Correspondence Address: MERCHANT & GOULD PC, P.O. BOX 2903, MINNEAPOLIS, MN, 55402-0903, US

(73) Assignee: Impinj, Inc., Seattle, WA (US)

(21) Appl. No.: 11/133,718

(22) Filed: May 19, 2005

Related U.S. Application Data
(60) Provisional application No. 60/667,188, filed on Mar. 30, 2005.

(51) Int. Cl. H01L 29/788

(52) U.S. Cl. 257/315

(57) ABSTRACT

Tunneling-enhanced, floating gate semiconductor devices and methods for forming such devices are described. In one embodiment, a p-n junction device is formed with a floating gate that is partially doped with n- and p-type impurities. Two regions on either side of an n+ doped region in the floating gate and a surface region on a substrate are implanted with the impurities based on a number of predetermined configurations. In another embodiment, a transistor type semiconductor device is configured with implanted impurities in two regions of its floating gate as well as two surface regions in its substrate. Enhanced tunneling junction enables use of lower tunneling voltages in applications such as programming NVM cells.

### RELATED APPLICATIONS

This application claims the benefit of U.S. Provisional Application Ser. No. 60/667,188 filed on Mar. 30, 2005, which is hereby claimed under 35 U.S.C. § 119(e). The referenced Provisional Application and related U.S. Utility application Ser. No. 10/813,907 (IMPJ-0027A) filed on Mar. 30, 2004; Ser. No. 10/814,866 (IMPJ-0027B) filed on Mar. 30, 2004; Ser. No. 10/814,868 (IMPJ-0027C) filed on Mar. 30, 2004; and Ser. No. 11/095,938 (IMPJ-0083) filed on Mar. 30, 2005 are incorporated herein by reference. Furthermore, this application may be found to be related to U.S. Utility application Ser. No. 10/356,645 (IMPJ-0018) filed on Jan. 31, 2003.

### FIELD OF THE INVENTION

The present invention relates to semiconductor devices, and more particularly, to devices and methods of forming such devices for providing tunneling-enhanced floating gate operations, to assist charge storing devices.

### BACKGROUND OF THE INVENTION

Memory elements may be classified in two main categories: volatile and nonvolatile. Volatile memory loses any data as soon as the system is turned off. Thus, it requires constant power to remain viable. Most types of random access memory (RAM) fall into this category. Non-volatile memory does not lose its data when the system or device is turned off. A non-volatile memory (NVM) device may be implemented as a read-out MOS transistor that has a source, a drain, an access or a control gate, and a floating gate. It is structurally different from a standard MOSFET in its floating gate, which is electrically isolated, or “floating”.

Another kind of device, often called a programming device, shares the floating gate and assists with handling the charge on the floating gate. Such a programming device is usually formed in conjunction with the read-out transistor.

In programming floating gate memory circuits, electrons are typically exchanged between the floating gate and the substrate by bi-directional tunneling through a thin silicon dioxide (SiO₂) layer. Tunneling is the process by which an NVM can be either erased or programmed and is usually dominant in thin oxides of thicknesses less than 12 nm. Storage of the charge on the floating gate allows the threshold voltage to be electrically altered between a low and a high value to represent logic 0 and 1, respectively. Other types of electron injection methods such as hot electron injection may also be employed in floating gate devices. In floating gate memory devices, charge or data is stored in the floating gate and is retained when the power is removed.

Floating gate devices are commonly used in memory circuits such as Electrically Programmable Read Only Memory (EPROM), Electrically Erasable and Programmable Read Only Memory (EEPROM), and Flash memory circuits. Cost, size, power consumption, and complexity are some of the major parameters that affect design considerations for a memory device, thereby the design of the floating gate programming device as well.

### SUMMARY

The disclosure facilitates tunneling-enhanced floating gate operation in a semiconductor device. Accordingly, the disclosure provides a programming and erasing circuit for memory devices.

In some embodiments, a junction device is configured with predetermined regions of its floating gate and a surface region implanted with p+ or n+ type impurities to enhance tunneling capability. As a result higher tunneling currents may be achieved without increasing the tunneling voltage, or same tunneling currents may be achieved for lower tunneling voltage values.

In other embodiments, a floating gate FET is configured with predetermined configurations of doped gate regions and surface regions. Devices according to embodiments may be employed to modify charges on a floating gate memory cell storing bit values based on the tunneling voltage.

While example embodiments are shown using a number of floating gate and surface regions, the principles disclosed herein may be implemented with fewer or more regions. Thus, the invention is not limited to the illustrated examples.

### BRIEF DESCRIPTION OF THE DRAWINGS

Non-limiting and non-exhaustive embodiments are described with reference to the following drawings.

FIG. 1A is a cross-sectional view of a tunneling-enhanced floating gate device;

FIG. 1B is a table showing different configurations for implanting regions of the tunneling-enhanced floating gate device of FIG. 1A with impurities of n- and p-type;

FIG. 2A is a cross-sectional view of the semiconductor device of FIG. 1A according to one embodiment;

FIG. 2B is a top view of a layout diagram of the tunneling-enhanced floating gate device of FIG. 2A;

FIG. 3A is a cross-sectional view of the tunneling-enhanced floating gate device of FIG. 1A according to another embodiment;

FIG. 3B is a top view of a layout diagram of the tunneling-enhanced floating gate device of FIG. 3A;

FIG. 4A is a cross-sectional view of a tunneling-enhanced floating gate Field Effect Transistor (FET) device;

FIG. 4B is a table showing different configurations for implanting regions of the tunneling-enhanced floating gate FET device of FIG. 4A with impurities of n- and p-type;

FIG. 5A is a cross-sectional view of FET device of FIG. 4A according to one embodiment;

FIG. 5B is a top view of a layout diagram of the FET device of FIG. 5A;

FIG. 6A is a cross-sectional view of the FET device of FIG. 4A according to another embodiment;

FIG. 6B is a top view of a layout diagram of the FET device of FIG. 6A;

FIG. 7 is a diagram comparing tunneling currents of a nominal pFET and an n+ doped pFET with changing tunneling voltage;

FIG. 8A is a schematic representation of a memory cell with a read-out device and a programming device that comprises the tunneling-enhanced floating gate device of FIG. 4A;

FIG. 8B is a cross-sectional view of the memory cell of FIG. 8A; and

FIG. 9 is a schematic representation of another memory cell with the read-out device comprising an inverter circuit and the programming device comprising the tunneling-enhanced floating gate device of FIG. 4A.

### DETAILED DESCRIPTION

Various embodiments of the present invention will be described in detail with reference to the drawings, where like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

Throughout the specification and claims, the following terms take at least the meanings explicitly associated herein, unless the context clearly dictates otherwise. The meanings identified below are not intended to limit the terms, but merely provide illustrative examples for the terms. The meaning of “a,” “an,” and “the” includes plural reference, the meaning of “in” includes “in” and “on.” The term “connected” means a direct electrical connection between the items connected, without any intermediate devices. The term “coupled” means either a direct electrical connection between the items connected or an indirect connection through one or more passive or active intermediary devices. The term “circuit” means either a single component or a multiplicity of components, either active and/or passive, that are coupled together to provide a desired function. The term “signal” means at least one current, voltage, charge, temperature, data, or other measurable quantity. The term “cell” means a unit NVM circuit comprising of a programming and a storage element that are arranged to store one bit.

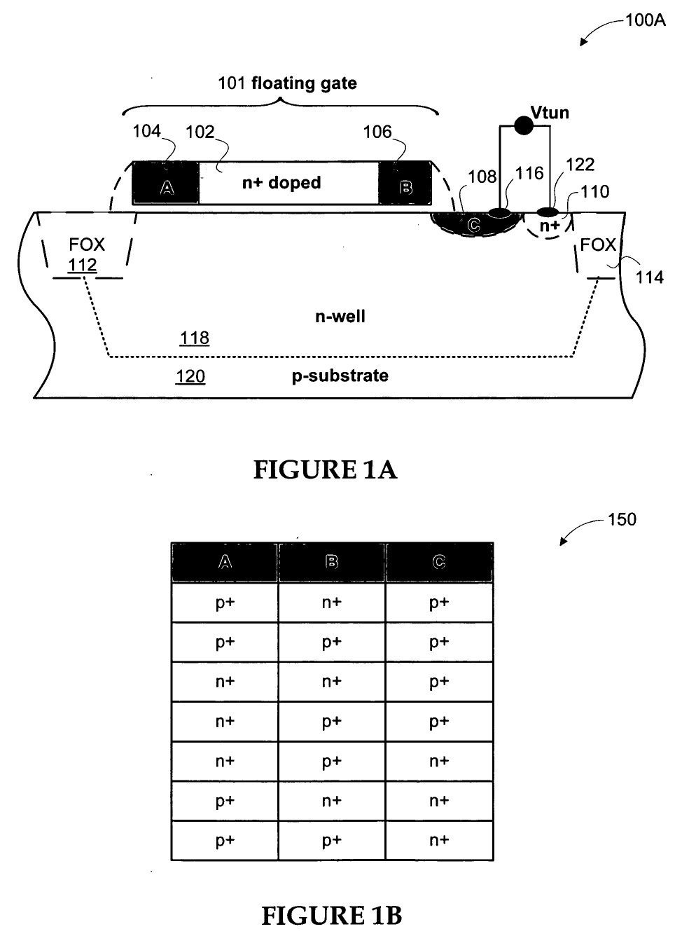

FIG. 1A is a cross-sectional view of tunneling-enhanced floating gate semiconductor device 100A according to one embodiment.

Semiconductor device 100A may be formed on substrate 120 that includes impurities of p-type. Substrate 120 includes n-well 118 that is doped with impurities of n-type and two optional field oxide regions 112 and 114 that may be formed along either edge of n-well 118. Embodiments may be implemented with one, both, or neither of field oxide regions 112 and 114. Semiconductor device 100A further includes in n-well 118 surface regions 108 (designated “C”) and 110. Surface region 110 includes impurities of n-type and may abut surface region 108 (“C”). Surface region 108 (“C”) may be implanted with impurities of p- or n-type as shown in table 150 of FIG. 1B.

Semiconductor device 100A also includes contact regions 116 and 122 in surface regions 108 (“C”) and 110, which are arranged to receive tunneling voltage Vtun. In one embodiment, surface region 108 (“C”) and surface region 110 may be overlapping, abutting, or separated by another region within n-well 118. A floating gate (101) is disposed over n-well 118 of semiconductor device 110A. Floating gate 101 may include different regions doped with p- and n-type impurities. According to one embodiment, floating gate 101 is divided into three regions: first region 104 (“A”), second region 102, and third region 106 (“B”), where third region 106 (“B”) located about surface region 108.

Second region 102 is implanted with impurities of n-type and located centrally within floating gate 101. First region 104 (“A”) and third region 106 (“B”) are located on opposite sides of second region 102 and may be implanted with impurities of p- or n-type as shown in table 150 of FIG. 1B. Third region 106 (“B”) and surface region 108 (“C”) may be arranged such that they overlap, do not overlap, or are approximately adjacent to each other.

Semiconductor device 100A maybe Silicon-On-Insulator (SOI) type and the substrate may include a relatively thin layer of Si deposited over a thin film of oxide embedded onto a relatively thick layer of Si. Semiconductor device 100A may also be Silicon-On-Sapphire (SOS) type and the substrate may include a relatively thin layer of Si over sapphire (Al₂O₃). In a further embodiment, semiconductor device 100A may be GaAs type and the substrate may include a thin layer of Ga deposited over a layer of As.

FIG. 1B includes table 150 showing different configurations for implanting regions of the tunneling-enhanced floating gate device of FIG. 1A with impurities of n- and p-type. Table 150 includes three columns, one for each doped region in semiconductor device 100A. First column is for first region 104 (“A”). Second column is for third region 106 (“B”). Third column is for surface region 108 (“C”). Each row of table 150 shows a configuration of implants for each of these regions that enable semiconductor device 100A to operate as a tunneling-enhanced floating gate device with lower tunneling voltages in applications where charges are to be adjusted in a shared floating gate structure.

An example application is a Non-Volatile Memory (NVM) cell, which may include a read-out circuit and a programming circuit that share a floating gate. In such an application, semiconductor device 100A may be used to charge and discharge the shared floating gate, thereby programming the NVM cell, with lower tunneling voltage or higher tunneling current. This may also result in faster programming speed for the NVM application.

As table 150 shows, a configuration, where all three regions are implanted with impurities of n-type is inoperable, therefore not included. While semiconductor device 100A is shown with floating gate 101 having three distinct regions and table 150 with configurations for this structure, the invention is not so limited. Other embodiments with more or fewer regions of floating gate 101, various shapes and transitions of the regions of floating gate 101 may be implemented without departing from a scope and spirit of the invention.

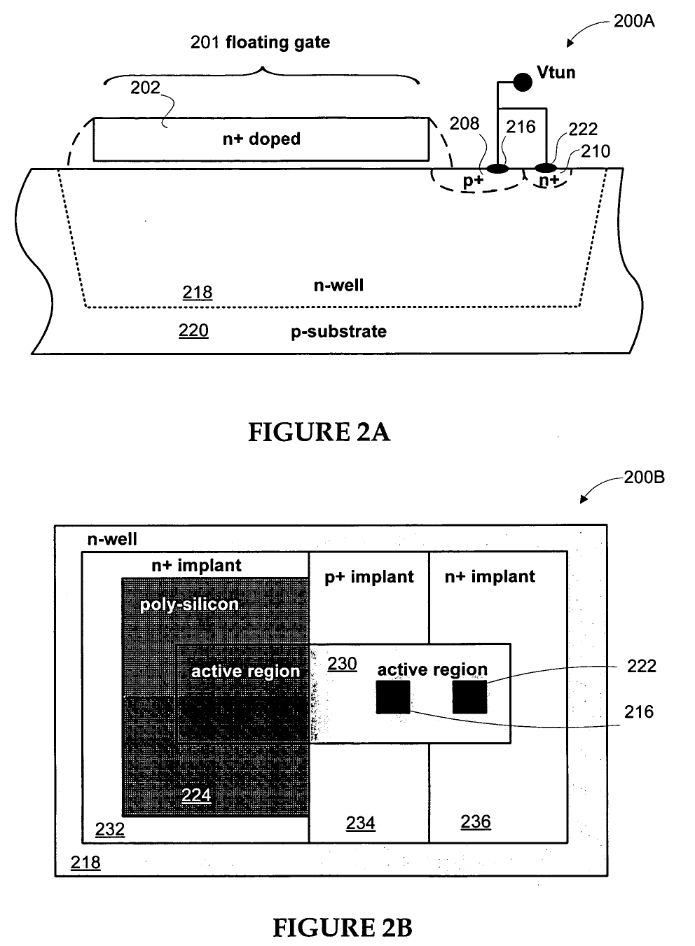

FIG. 2A is a cross-sectional view of semiconductor device 200A. Semiconductor device 200A is one embodiment of the tunneling-enhanced floating gate device of FIG. 1A with the entire floating gate implanted with impurities of n-type.

Parts of semiconductor device 200A that are similarly numbered in semiconductor device 100A of FIG. 1A are arranged to function in a likewise manner. In semiconductor device 200A, all three regions of floating gate 201 described in conjunction with FIG. 1A are implanted with impurities of n-type. Surface region 208, implanted with impurities of p-type is arranged to supply minority carriers when the junction is biased in inversion.

Employing the n-doped floating gate together with the p-doped surface region for the junction enables semiconductor device 200A to operate at lower breakdown voltages compared to p-doped poly-gate type junction devices. Lower tunneling voltages enable, in return, smaller voltage sources such as charge pumps, HV switches, and the like, in a memory application.

For applications, where retention is less of a concern, faster programming and lower maximum voltage may be achieved. For example, in memory circuit applications may employ standard logic devices with enhanced reliability and performance by using a tunneling-enhanced junction device for programming the memory cells.

FIG. 2B is a top view of layout diagram 200B of semiconductor device 200A of FIG. 2A with the entire floating gate implanted with impurities of n-type.

Layout diagram 200B includes n-well 218 at bottom layer. Other layers over n-well 218 include adjacent n+ implant region 232, p+ implant region 234, and n+ implant region 236, respectively. Active region 230 is shown at top layer with contact regions 216 and 222 on it, where tunneling voltage Vtun may be provided. A portion of active region 230 expands over poly-silicon area 224 over n+ implant region 232.

N+ implant region 232 corresponds to surface region 210 and the entire floating gate of semiconductor device 200A. P+ implant region 234 corresponds to surface region 208 of semiconductor device 200A. Finally, n+ implant region 236 corresponds to n-doped surface region 210 of semiconductor device 200A.

In one embodiment, one or two field oxide layers (not shown) may be provided within n-well 218 on opposite sides of n+ implant region 232 and n+ implant region 236. In another embodiment, the structure shown in the figure may be formed directly over p+ doped substrate.

In an example application, where semiconductor device 200A may be used for programming purposes, the floating gate (poly-silicon area 224) may be extended beyond n-well 218 and shared with another circuit, such as a read-out circuit of a memory cell.

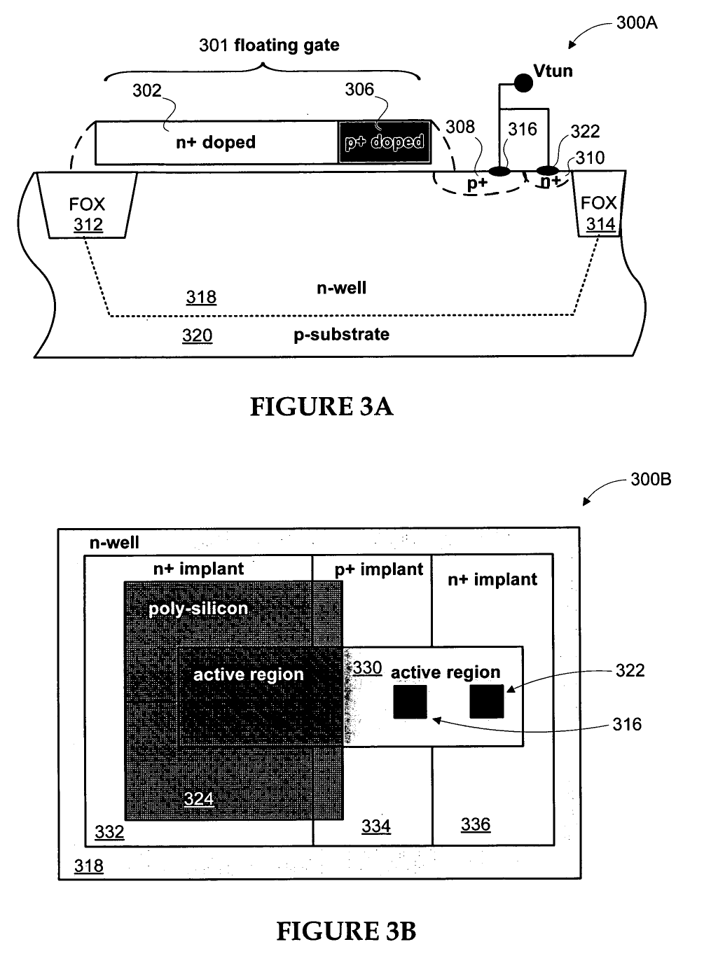

FIG. 3A is a cross-sectional view of semiconductor device 300A. Semiconductor device 300A is another embodiment of the tunneling-enhanced floating gate device of FIG. 1A with the floating gate partially implanted with impurities of n-type.

Parts of semiconductor device 300A that are similarly numbered in semiconductor device 200A of FIG. 2A are arranged to function in a likewise manner. Shared floating gate 301 of semiconductor device 300A is constructed differently.

In semiconductor device 300A, a region of floating gate 301 away from the surface region 308 is doped with impurities of n-type, therefore combined with the middle region. The combined region is designated by reference numeral 302. The remaining region 306 is implanted with impurities of p-type.

Semiconductor device 300A also includes optional field oxide regions 312 and 314 on opposite sides of n-well 318. Surface region 308, implanted with impurities of p-type, and p+ doped floating gate region 306 are arranged to supply minority carriers when the junction is biased in inversion.

FIG. 3B is a top view of layout diagram 300B of semiconductor device 300A of FIG. 3A with the floating gate partially implanted with impurities of n-type.

Layout diagram 300B includes n-well 318 at bottom layer. Other layers over n-well 318 include adjacent n+ implant region 332, p+ implant region 334, and n+ implant region 336, respectively. Active region 330 is shown at top layer with contact regions 316 and 322 on it, where tunneling voltage Vtun is may be provided. A portion of active region 330 is within poly-silicon area 324 over n+ implant region 332.

Poly-silicon area includes n+ implant and p+ implant portions corresponding to n+ doped and p+ doped regions 302 and 306 of the floating gate, respectively. N+ implant region 332 corresponds to the n+ doped portion of the floating gate. P+ implant region 334 corresponds to region 306 of the floating gate and surface region 308 of semiconductor 300A. Finally, n+ implant region 336 corresponds to n+ doped surface region 310 of the semiconductor device. In one embodiment, the structure shown in the figure may be formed directly over p+ doped substrate.

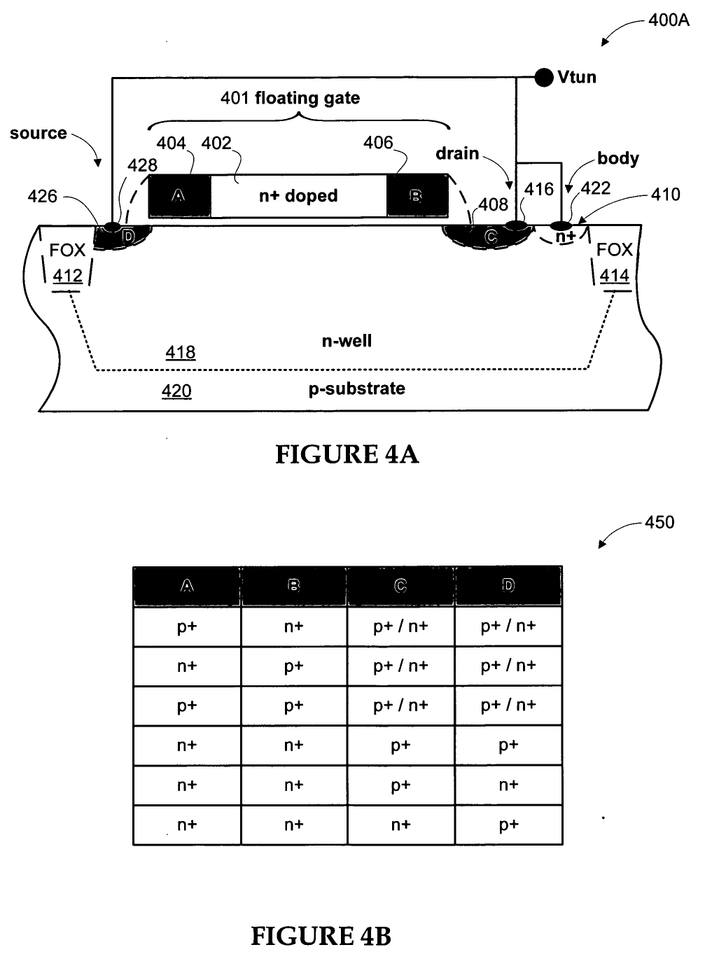

FIG. 4A is a cross-sectional view of tunneling-enhanced floating gate FET device 400A according to one embodiment.

FET device 400A may be formed on substrate 420 that includes impurities of p-type. Substrate 420 includes n-well 418 that is doped with impurities of n-type and two optional field oxide regions 412 and 414 that may be formed along either edge of n-well 418. Embodiments may be implemented with one, both, or neither of field oxide regions 412 and 414. FET device 400A further includes in n-well 418 first surface region 426 (designated “D”), second surface region 408 (designated “C”), and third surface region 410. Third surface region 410 includes impurities of n-type and may abut second surface region 408 (“C”). First surface region 426 (“D”) and second surface region 408 (“C”) may be implanted with impurities of p- or n-type as shown in table 450 of FIG. 4B. First surface region 426 (“D”) and second surface region 408 (“C”) form boundaries of a channel area, over which floating gate 401 is disposed.

Floating gate 401 may include different regions doped with p- and n-type impurities. According to one embodiment, floating gate 401 is divided into three adjacent regions: first region 404 (“A”), second region 402, and third region 406 (“B”), where second region 402 is implanted with impurities of n-type and located centrally within floating gate 401. First region 404 and third region 406 are located on opposite sides of second region 402 and may be implanted with impurities of p- or n-type as shown in table 450 of FIG. 4B.

First region 404 (“A”) and third region 406 (“B”) are located approximately over first surface region 426 (“D”) and second surface region 408 (“C”), respectively. The regions of floating gate 401 and the respective surface regions may be arranged such that they overlap, do not overlap, or are approximately adjacent to each other.

FET device 400A also includes contact regions 428, 416, and 422 in surface regions 426, 408, and 410, respectively. Contact region 428 corresponds to a source terminal of FET device 400A. Contact region 416 corresponds to a drain terminal of FET device 400A. Contact region 422 corresponds to a body terminal of FET device 400A. In one embodiment, the three contact regions are coupled together and arranged to receive tunneling voltage Vtun.

In another embodiment, second surface region 408 and third surface region 410 may be overlapping, abutting, or separated by another region within n-well 418. FET device 400A maybe Silicon-On-Insulator (SOI) type and the substrate may include a relatively thin layer of Si deposited over a thin film of oxide embedded onto a relatively thick layer of Si. FET device 400A may also be Silicon-On-Sapphire (SOS) type and the substrate may include a relatively thin layer of Si over sapphire (Al₂O₃). In a further embodiment, FET device 400A may be GaAs type and the substrate may include a thin layer of Ga deposited over a layer of As.

FIG. 4B includes table 450 showing different configurations for implanting regions of the tunneling-enhanced floating gate FET device of FIG. 4A with impurities of n- and p-type. Table 150 includes four columns, one for each doped region in FET device 400A. First column is for first region 404 (“A”). Second column is for third region 406 (“B”). Third column is for second surface region 426 (“C”). Fourth column is for first surface region 408 (“D”). Each row of table 450 shows a configuration of implants for each of these regions that enable FET device 400A to operate as a tunneling-enhanced floating gate FET with lower tunneling voltages in applications where charges are to be adjusted in a shared floating gate structure.

Similar to the example application described in conjunction with FIG. 1B, FET device 400A with its configuration shown in table 450 may be used as a programming circuit in a Non-Volatile Memory (NVM) cell, and share floating gate 401 with a read-out circuit. In such an application, FET device 400A may be used to charge and discharge the shared floating gate, thereby programming the NVM cell, with lower tunneling voltage or higher tunneling current. This may also result in faster programming speed for the NVM application.

By way of example, first row of table 450 indicates configurations where first region 404 (“A”) and third region 406 (“B”) of floating gate 401 are doped with impurities of p+ and n+ type, respectively. First surface region 426 (“D”) and second surface region 416 (“C”) may be implanted with impurities of either p+ or n+ type for valid configurations for this condition.

As table 450 shows, not all configurations are included. Some configurations do not result in proper operation or tunneling-enhanced operation. While FET device 400A is shown with floating gate 401 having three distinct regions and table 450 with configurations for this structure, the invention is not so limited. Other embodiments with more or fewer regions of the floating gate, various shapes and transitions of the regions of the floating gate may be implemented without departing from a scope and spirit of the invention.

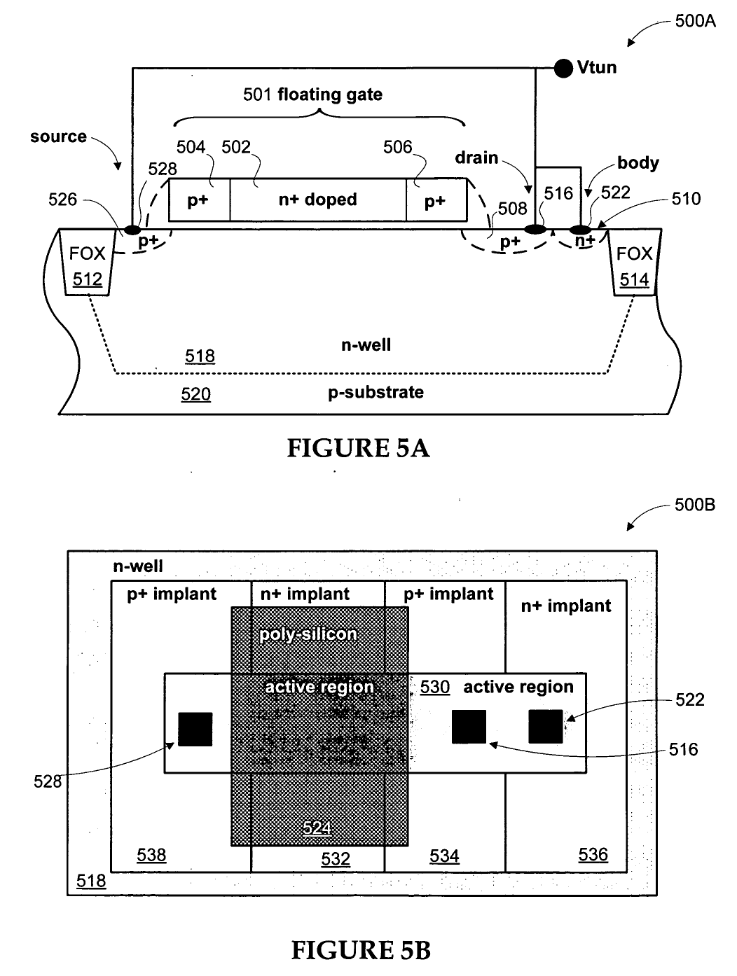

FIG. 5A is a cross-sectional view of FET device 500A. FET device 500A is one embodiment of the tunneling-enhanced floating gate FET device of FIG. 4A with the floating gate partially implanted with impurities of n-type and p-type.

Parts of FET device 500A that are similarly numbered in FET device 400A of FIG. 4A are arranged to function in a likewise manner. In FET device 500A, first and third regions 504 and 506 of floating gate 501 are implanted with impurities of p-type. First and second surface regions 526 and 508 are also implanted with impurities of p-type and arranged to supply minority carriers when the junction is biased in inversion.

Employing the partially n- and p-doped floating gate 501 together with the p-doped surface regions for the junction channel enables FET device 500A to operate at lower breakdown voltages compared to p-doped polygate type FET devices. Lower tunneling voltages enable, in return, smaller voltage sources such as charge pumps, HV switches, and the like, in a memory application.

FIG. 5B is a top view of layout diagram 500B of FET device 500A. Layout diagram 500B includes n-well 518 at bottom layer. Other layers over n-well 518 include adjacent p+ implant region 538, n+ implant region 532, p+ implant region 534, and n+ implant region 536, respectively. Active region 530 is shown at top layer with contact regions 528, 516, and 522. Tunneling voltage Vtun may be provided to all contact regions at once. Poly-silicon area 524 of the floating gate spreads over n+ implant region 532, and partially over p+ implant regions 534 and 538.

P+ implant region 538 corresponds to first surface region 526 and first region of the floating gate 504. N+ implant region 532 corresponds to second region 502 of the floating gate. P+ implant region 534 corresponds to third region 506 of the floating gate and second surface region 508 of FET device 500A. Finally, n+ implant region 536 corresponds to n+ doped third surface region 510 of FET device 500A.

In one embodiment, field oxide layers 512 and 514 define boundaries of n-well 518 on opposite sides of p+ implant region 538 and n+ implant region 536. In another embodiment, the structure shown in the figure may be formed directly over p+ doped substrate.

In an example application, where FET device 500A may be used for programming purposes, the floating gate (poly-silicon area 524) may be extended beyond n-well 518 and shared with another circuit, such as a read-out circuit of a memory cell.

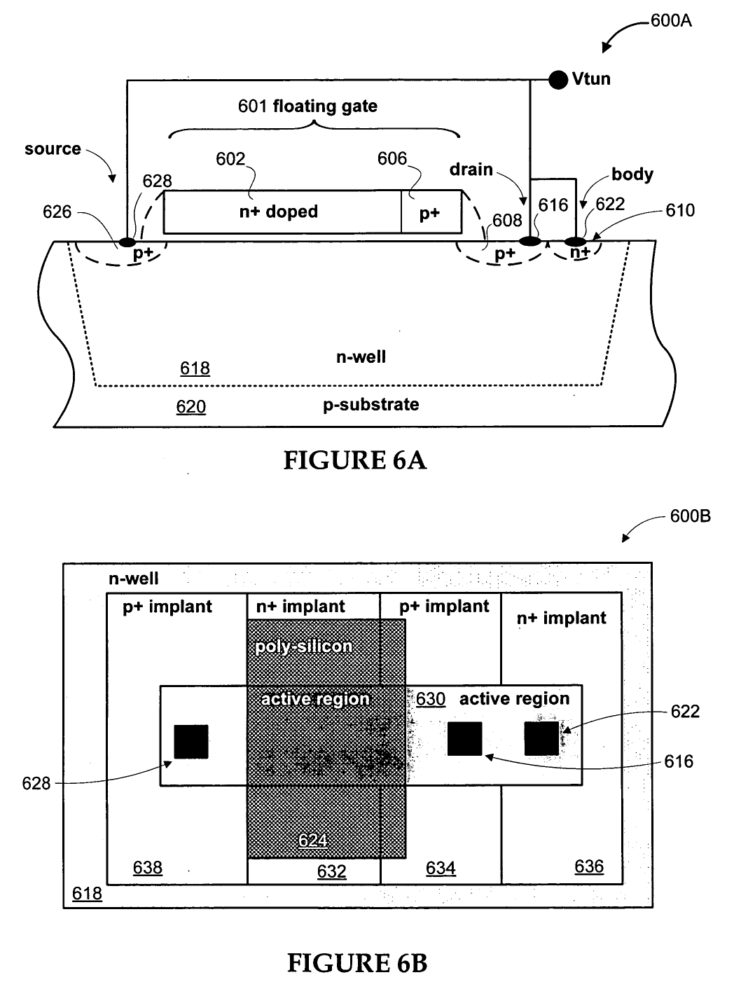

FIG. 6A is a cross-sectional view of FET device 600A. FET device 600A is another embodiment of the tunneling-enhanced floating gate FET device of FIG. 4A with the floating gate partially implanted with impurities of n- and p-type.

Parts of FET device 600A that are similarly numbered in FET device 500A of FIG. 5A are arranged to function in a likewise manner. Shared floating gate 601 of FET device 600A is constructed differently.

In FET device 600A, a first region of floating gate 601 along with the centrally located second region (designated together by reference numeral 602) is doped with impurities of n-type. The remaining region 606 of floating gate 601 is implanted with impurities of p-type.

FET device 600A does not include optional field oxide regions 412 and 414 of the FET device 400A. First surface region 626 and second surface region 608, implanted with impurities of p-type, and p+ doped floating gate region 606 are arranged to supply minority carriers when the junction is biased in inversion.

FIG. 6B is a top view of layout diagram 600B of FET device 600A of FIG. 6A with the floating gate partially implanted with impurities of n-type.

Layout diagram 600B includes n-well 618 at bottom layer. Other layers over n-well 618 include adjacent p+ implant region 638, n+ implant region 632, p+ implant region 634, and n+ implant region 636, respectively. Active region 630 is shown at top layer with contact regions 628, 616, and 622. Tunneling voltage Vtun may be provided to all contact regions at once. Poly-silicon area 624 of the floating gate spreads over n+ implant region 632, and partially over p+ implant region 634.

P+ implant region 638 corresponds to first surface region 626. N+ implant region 632 corresponds to combined regions 502 of the floating gate. P+ implant region 634 corresponds to third region 606 of the floating gate and second surface region 608 of FET device 600A. Finally, n+ implant region 636 corresponds to n+ doped third surface region 610 of FET device 600A. In one embodiment, the structure shown in the figure may be formed directly over p+ doped substrate.

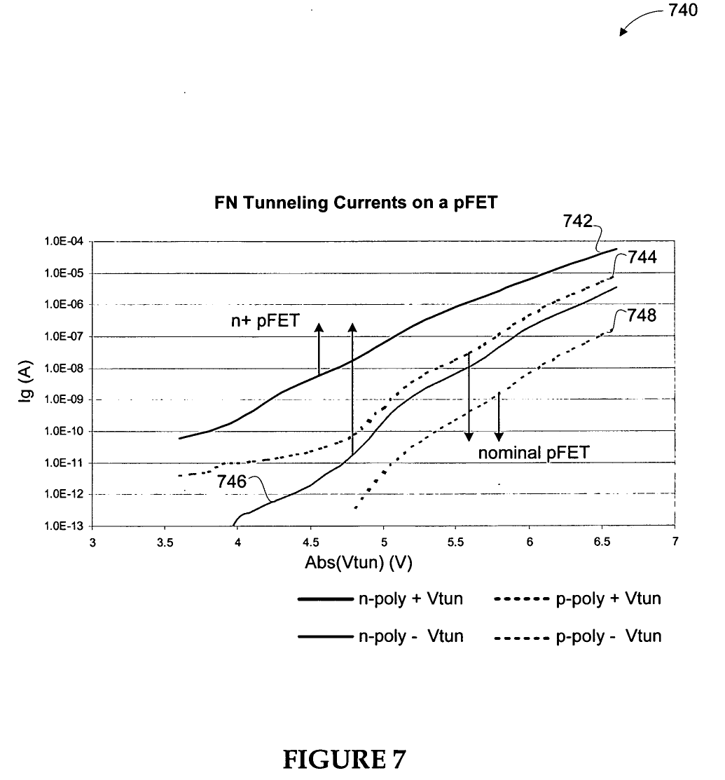

FIG. 7 illustrates diagram 740 comparing tunneling currents of a nominal pFET and an n+ doped pFET with changing tunneling voltage. Vertical axis of diagram 740 shows tunneling current Ig in Amperes. Horizontal axis of diagram 740 shows absolute value of tunneling voltage Vtun in Volts.

Diagram 740 includes four voltage-current curves. First, curve 742 represents a change of the tunneling current Ig with increasing tunneling voltage Vtun in the nominal n+ pFET when the tunneling voltage is applied with positive polarity. Curve 746 represents a change of the tunneling current Ig with increasing tunneling voltage Vtun in the nominal n+ pFET when the tunneling voltage is applied with negative polarity.

Curves 744 and 748 represent changes of the tunneling current Ig with increasing tunneling voltage Vtun in the nominal p+ pFET when the tunneling voltage is applied with positive and negative polarity, respectively.

As diagram 740 shows, the voltage-current curves for the nominal n+ pFET are lower than the curves for the nominal p+ pFET meaning higher tunneling current may be achieved in a FET device according to embodiments of the present invention with lower tunneling voltage values. In some cases, the difference in a value of the tunneling voltage for the Ig may be by an order of magnitude between the two FET types.

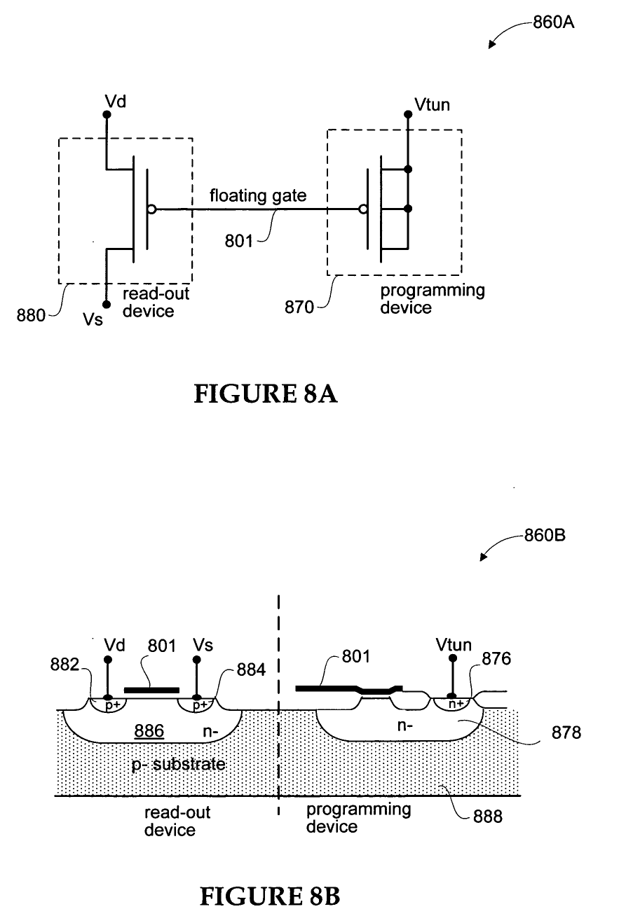

FIG. 8A is a schematic representation of example memory cell 860A with a read-out device and a programming device that comprises the tunneling-enhanced floating gate device of FIG. 4A.

In general, dual-transistor NVM cells operate as follows. During an erase operation, electrons are removed from a floating gate of the NVM cell, thereby adjusting and lowering the switch point voltage of the dual transistor NVM cell. During a program operation, electrons are inserted onto the floating gate of the NVM cell, thereby adjusting and raising the switch point voltage of the dual transistor NVM cell. Thus, during program and erase operations, the switch point voltages of selected NVM cells are changed. During a read operation, read voltages are applied to selected NVM cells. In response, output voltage of these selected NVM cells reflect a bit value based on the stored charges in their floating gate.

Floating gate type NVM cells may include charge adjustment circuits that are arranged to inject electrons to or remove electrons from the floating gate of the storage element employing mechanisms such as impact-ionized hot-electron injection, Fowler-Nordheim (FN) tunneling, channel hot-electron tunneling, or band-to-band tunneling induced electron injection.

Memory cell 860A includes read-out device 880 and programming device 870. In one embodiment, read-out device 880 comprises a pFET transistor circuit with drain and source voltages Vd and Vs. Programming device 870 may include a tunneling-enhanced floating gate FET device like FET device 400A of FIG. 4A with tunneling voltage applied to its source, drain, and body terminals. Read-out device 880 and programming device 870 share floating gate 801.

The FETs of the NVM cell may include at least one of a Metal-Oxide Field Effect Transistor (MOSFET), a FinFET, and a Metal-Semiconductor Field Effect Transistor (MESFET). Furthermore, the shared gate terminal is adapted to be charged by at least one of impact-ionized hot-electron injection, Fowler-Nordheim (FN) tunneling, channel hot-electron tunneling, and band-to-band tunneling induced electron injection. The shared gate terminal may be discharged by FN tunneling.

FIG. 8B is a cross-sectional view of example memory cell 860B. Memory cell 860B is one embodiment of memory cell 860A of FIG. 8A.

The FETs acting as read-out device and programming device may be formed on the same p-substrate (888). The read-out device may include p-doped surface regions 882 and 884 forming a channel within n-well 886. Surface region 882 may be arranged to receive Vs, and surface region 884 may be arranged to receive Vd through contact regions (not shown) within the respective surface regions. Floating gate 801 is disposed over the channel formed between surface regions 882 and 884.

The programming device is shown in a simplified form in FIG. 8B and may include any of the parts described in conjunction with FIGS. 1A and 4A. In the simplified representation, the programming device includes n+ doped surface region 876 within n-well 878. Surface region 876 is arranged to receive tunneling voltage Vtun to charge or discharge floating gate 801, which is also disposed over n-well 878.

During a programming or an erase operation, electrons are added or removed from floating gate 801, thereby adjusting a switch point voltage of the read-out device such that its output voltage corresponds to “1” or “0”, respectively, when supply voltage is applied to the read-out device. Accordingly, the read-out device's output voltage reflects a bit value based on the stored charges in the floating gate.

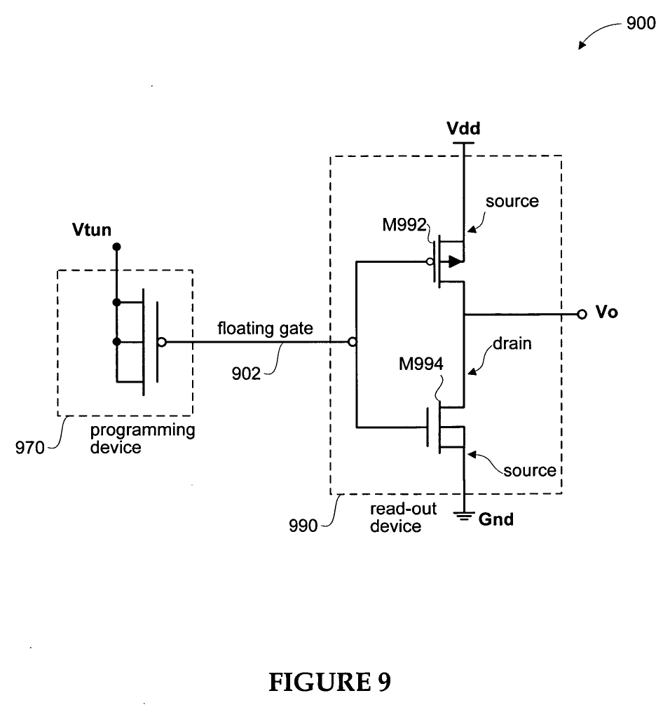

FIG. 9 is a schematic representation of another example memory cell (900) with the read-out device comprising an inverter circuit and the programming device comprising the tunneling-enhanced floating gate device of FIG. 4A.

Memory cell 900 includes programming device 970 and read-out device 990. Programming device 970 may include a tunneling-enhanced floating gate FET device similar to the programming device 870 of FIG. 8A and operate likewise. Read-out device 990 includes FETs M992 and M994 that are configured to operate as an inverter and share a floating gate terminal (901). One of the FETs (M992) is p-type, the other (M994) n-type. The shared gate (901) is also shared with programming device 970.

In one embodiment, a source terminal of M992 is coupled to high supply voltage Vdd and a drain terminal of second FET M994 is coupled to a drain terminal of first FET M992 such that output voltage Vo is provided from the drain terminal of second FET M992. A source terminal of second FET M994 is coupled to low supply voltage Gnd.

NVM cell retention is generally dominated by n-FET long-term detention. If the n-FET has an n+ polysilicon gate, it has worse retention. p-FETs store charges longer than n-FETs for a given oxide thickness. A value of the output voltage Vo depends on a charge level of floating gate 901 as described previously, and reflects a bit value stored in memory cell 900.

In other embodiments, the read-out device may include transistor pairs arranged to operate as a NOR circuit or as a NAND circuit. Output voltage Vo in such embodiments corresponds to “0” or “1” depending on the charge levels of the floating gates as programmed by the input (tunneling) voltages. Other logic circuits such as XOR, XNOR, and the like, may be implemented without departing from a scope and spirit of the invention.

The examples provided above in FIGS. 8 and 9 are for illustration purposes and do not constitute a limitation on the present invention. Other embodiments may be implemented using other logic circuit types and transistor types without departing from the scope and spirit of the invention. Further embodiments may include FinFETs, dual gate MOSFETs, MESFETs, GaAs FETs, and other MOS devices.

The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. A tunneling-enhanced floating gate device, comprising:
a substrate that includes impurities of p-type;
an n-well within the substrate that includes impurities of n-type;
a floating gate structure disposed over the n-well, wherein the floating gate structure includes a first region, a centrally located second region that is doped with implants of n-type impurities, and a third region; and
a first surface region in the n-well, wherein the first surface region is located about the third region of the floating gate structure.

2. The device of claim 1, wherein
the first region and the third region are doped with implants of at least one of a first type and a second type impurities; and
the first surface region is doped with implants of the first type impurities.

3. The device of claim 1, wherein
the first region is doped with implants of one of a first type and a second type impurities;
the third region is doped with implants of another of the first type and the second type impurities; and
the first surface region is doped with implants of the second type impurities.

4. The device of claim 1, wherein
the first region and the third region are doped with implants of a first type impurities; and
the first surface region is doped with implants of a second type impurities.

5. The device of claim 4, wherein
the first type impurities include p-type impurities; and
the second type impurities include n-type impurities.

6. The device of claim 1, further comprising:
a second surface region that is located about the first surface region away from the floating gate structure, wherein the second surface region is doped with implants of n-type impurities.

7. The device of claim 6, wherein
the first surface region and the second surface region are one of overlapping, abutting, and separated by another region.

8. The device of claim 6, further comprising:
a first contact region in the first surface region that is arranged to receive a tunneling voltage.

9. The device of claim 6, further comprising:
a second contact region in the second surface region that is also arranged to receive the tunneling voltage.

10. The device of claim 1, wherein
the floating gate structure is arranged such that the third region and the first surface region are one of overlapping, non-overlapping, and approximately adjacent thereto.

11. The device of claim 1, further comprising:
at least one of a first field oxide region and a second field oxide region that are arranged to define boundaries of the n-well.

12. A method for creating a tunneling-enhanced floating gate device, comprising:
forming a substrate that includes impurities of p-type;
forming an n-well within the substrate that includes impurities of n-type;
forming a floating gate structure disposed over the n-well, wherein the floating gate structure includes a first region, a centrally located second region that is doped with implants of n-type impurities, and a third region;
forming a first surface region in the n-well, wherein the first surface region is located about the third region of the floating gate structure; and
forming a second surface region that is located about the first surface region away from the floating gate structure, wherein the second surface region is doped with implants of n-type impurities.

13. The method of claim 12, further comprising:
forming a first contact region in the first surface region that is arranged to receive a tunneling voltage;
forming a second contact region in the second surface region that is also arranged to receive the tunneling voltage; and
forming at least one field oxide region at one end of the n-well.

14. The method of claim 12, further comprising:
doping the first region and the third region with implants of at least one of a first type and a second type impurities; and
doping the first surface region with implants of the first type impurities.

15. The method of claim 12, further comprising:
doping the first region with implants of one of a first type and a second type impurities;
doping the third region with implants of another of the first type and the second type impurities; and
doping the first surface region with implants of the second type impurities.

16. The method of claim 12, further comprising:
doping the first region and the third region with implants of one of a first type and a second type impurities; and
doping the first surface region with implants of the second type impurities.

17. The method of claim 16, wherein
the first type impurities include p-type impurities; and
the second type impurities include n-type impurities.

18. A tunneling-enhanced floating gate device, comprising:
a substrate that includes impurities of p-type;
an n-well within the substrate that includes impurities of n-type;
a first surface region in the n-well;
a second surface region in the n-well;
a floating gate structure disposed over a region in the n-well defined by the first surface region and the second surface region, wherein the floating gate structure includes a first region, a centrally located second region that is doped with implants of n-type impurities, and a third region; and
a third surface region that is located about the second surface region away from the floating gate structure, wherein the third surface region is doped with implants of n-type impurities.

19. The device of claim 18, wherein
the first surface region and the second surface region are doped with implants of at least one of a first type and a second type impurities; and
the first region is doped with implants of one of the first type and the second type impurities; and
the third region is doped with implants of another of the first type and the second type impurities.

20. The device of claim 18, wherein
the first surface region and the second surface region are doped with implants of at least one of a first type and a second type impurities; and
the first region and the third region are doped with implants of the first type impurities.

21. The device of claim 18, wherein
the first surface region is doped with implants of one of a first type and a second type impurities;
the second surface region is doped with implants of another of the first type and the second type impurities; and
the first region and the third region are doped with implants of the second type impurities.

22. The device of claim 18, wherein
the first surface region and the second surface region are doped with implants of a first type impurities; and
the first region and the third region are doped with implants of a second type impurities.

23. The device of claim 22, wherein
the first type impurities include p-type impurities; and
the second type impurities include n-type impurities.

24. The device of claim 18, further comprising:
a first contact region in the first surface region;
a second contact region in the second surface region; and
a third contact region in the third surface region, wherein the contact regions are arranged to receive a tunneling voltage.

25. The device of claim 24, wherein
the first contact region is a source terminal;
the second contact region is a drain terminal; and
the third surface region is a body terminal.

26. The device of claim 24, wherein
the tunneling-enhanced floating gate device is a field effect transistor (FET) comprising at least one of: a MOSFET, a FinFET, and a MESFET.

27. The device of claim 24, wherein
the tunneling-enhanced floating gate device is arranged to receive a tunneling voltage to adjust charges on the floating gate structure that is coupled to a read-out circuit of a memory cell.

28. The device of claim 18, further comprising:
at least one of a first field oxide region and a second field oxide region that are arranged to define boundaries of the n-well.

29. The device of claim 18, wherein
the second surface region and the third surface region are at least one of overlapping, abutting, and separated by another region.

30. The device of claim 18, wherein
the floating gate structure is arranged such that the first region and the first surface region are one of overlapping, non-overlapping, and approximately adjacent thereto.

31. The device of claim 18, wherein
the floating gate structure is arranged such that the third region and the second surface region are one of overlapping, non-overlapping, and approximately adjacent thereto.

32. The device of claim 18, wherein
the floating gate structure is adapted to be charged by at least one of: impact-ionized hot-electron injection, Fowler-Nordheim (FN) tunneling, channel hot-electron injection, and band-to-band tunneling induced electron injection.

33. The device of claim 18, wherein
the floating gate structure is adapted to be discharged by FN tunneling, impact-ionization induced hot-hole injection, and band-to-band tunneling induced hot-hole injection.

34. The device of claim 18, wherein
the tunneling-enhanced floating gate device is of Silicon-On-Insulator (SOI) type and the substrate comprises a relatively thin layer of Si deposited over a thin film of oxide embedded onto a relatively thick layer of Si.

35. The device of claim 18, wherein
the tunneling-enhanced floating gate device is of Silicon-On-Sapphire (SOS) type and the substrate comprises a relatively thin layer of Si over sapphire (Al₂O₃).

36. The device of claim 18, wherein
the tunneling-enhanced floating gate device is of GaAs type and the substrate comprises a thin layer of Ga deposited over a layer of As.

37. A method for creating a tunneling-enhanced floating gate device, comprising:
forming a substrate that includes impurities of p-type;
forming an n-well within the substrate that includes impurities of n-type;
forming a first surface region in the n-well;
forming a second surface region in the n-well;
forming a floating gate structure disposed over a region in the n-well defined by the first surface region and the second surface region, wherein the floating gate structure includes a first region, a centrally located second region that is doped with implants of n-type impurities, and a third region; and
forming a third surface region that is located about the second surface region away from the floating gate structure, wherein the third surface region is doped with implants of n-type impurities.

38. The method of claim 37, further comprising:
forming a first contact region in the first surface region;
forming a second contact region in the second surface region;
forming a third contact region in the third surface region, wherein the contact regions are arranged to receive a tunneling voltage; and
forming at least one of a first field oxide region and a second field oxide region that define boundaries of the n-well.

39. The method of claim 37, further comprising:
doping the first surface region and the second surface region with implants of at least one of a first type and a second type impurities;
doping the first region with implants of one of the first type and the second type impurities; and
doping the third region with implants of another of the first type and the second type impurities.

40. The method of claim 37, further comprising:
doping the first surface region and the second surface region with implants of at least one of a first type and a second type impurities; and
doping the first region and the third region with implants of the first type impurities.

41. The method of claim 37, further comprising:
doping the first surface region with implants of one of a first type and a second type impurities;
doping the second surface region with implants of another of the first type and the second type impurities; and
doping the first region and the third region with implants of one of the second type impurities.

42. The method of claim 37, further comprising:
doping the first surface region and the second surface region with implants of a first type impurities; and
doping the first region and the third region with implants of a second type impurities.

43. The method of claim 42, wherein
the first type impurities include p-type impurities; and
the second type impurities include n-type impurities.
